(19) United States
(12) Patent Application Publication
(10) Pub. No.: US 2026/0371747 A1
(43) Pub. Date: Nov. 19, 2026

(54) COPPER-CADMIUM-NICKEL CHROMIUM SPINEL OXIDE BASED PHOTODIODE

(71) Applicant: Imam Abdulrahman Bin Faisal University, Dammam (SA)

(72) Inventors: Mohamed Lamjed Youssef BOUAZIZI, Dammam (SA); Mussad Mohammed AL-ZAHRANI, Dammam (SA); Sobhi HCINI, Sidi Bouazizi (TN); Mohammed Baqer Mohammed AL KHALAF, Dammam (SA)

(73) Assignee: Imam Abdulrahman Bin Faisal University, Dammam (SA)

(21) Appl. No.: 19/208,016

(22) Filed: May 14, 2025

(51) Int. Cl. H10F 30/222

(52) U.S. Cl. CPC H10F 30/222

(57) ABSTRACT

A photodiode includes a first electrode having an indium gallium (InGa) layer, a second electrode having a zinc oxide (ZnO) layer, and a copper-cadmium-nickel (Cu—Cd—Ni) spinel chromite layer including copper-cadmium-nickel chromium oxide (Cu_{0.4}Cd_{0.3}Ni_{0.3}Cr₂O₄). The Cu—Cd—Ni spinel chromite layer is present in a layer between the first electrode and the second electrode. The ZnO layer is a transparent outermost layer that is directly adjacent to the Cu—Cd—Ni spinel chromite layer.

### BACKGROUND

### Technical Field

The present disclosure is directed to a photodiode, and more particularly, a photodiode based on copper-cadmium-nickel chromium spinel oxide (Cu_{0.4}Cd_{0.3}Ni_{0.3}Cr₂O₄).

### Description of Related Art

The ‘background’ description provided herein is for the purpose of generally presenting the context of the disclosure. Work of the presently named inventors, to the extent it is described in this background section, as well as aspects of the description which may not otherwise qualify as prior art at the time of filing, are neither expressly nor impliedly admitted as prior art against the present disclosure.

The growing demand for accurate and reliable ultraviolet (UV) detection has driven research and development in UV photodiodes, which are required for technologies in fields such as environmental monitoring, healthcare, astronomy, and material science. However, existing UV detection technologies face challenges due to limitations such as low sensitivity, inadequate spectral response, instability, and short lifespan.

Recent advancements in UV photodetectors have led to the exploration of organic-inorganic hybrid photodetectors that exhibit good response in both the UV and visible regions.

These hybrids offer promising solutions, yet many still rely on compounds containing rare or toxic elements, such as indium (In), gallium (Ga), germanium (Ge), cadmium (Cd), sulfur (S), and selenium (Se), raising concerns about potential health and environmental hazards. While there have been reports of hybrid visible light photodetectors utilizing earth-abundant and non-toxic elements, these devices often lack self-powered operation, limiting their practical use. In parallel, the development of wide band-gap semiconductor nanomaterials with dimensions ranging from 1-100 nanometers (nm), including SnO₂, ZnS, ZnSe, TiO₂, MoS₂, ZnO, Nb₂O₅, NiCo₂O₄, Ga₂O₃, K₂Nb₈O₂₁, and Zn₂GeO₄, has been explored to enhance UV detection. These nanomaterials offer unique properties such as improved responsivity and photoconductivity gain due to their high surface area-to-volume ratios.

Each of the aforementioned innovations suffers from one or more drawbacks hindering their adoption. Accordingly, it is one object of the present disclosure to provide a photodiode that may circumvent these limitations by offering enhanced light sensitivity, improved detectivity, and greater efficiency.

### SUMMARY

In an exemplary embodiment, a photodiode is described. The photodiode includes a first electrode having an indium gallium (InGa) layer, a second electrode having a zinc oxide (ZnO) layer, and a copper-cadmium-nickel (Cu—Cd—Ni) spinel chromite layer including a copper-cadmium-nickel chromium spinel oxide (Cu_{0.4}Cd_{0.3}Ni_{0.3}Cr₂O₄). The Cu—Cd—Ni spinel chromite layer is present in a layer between the first electrode and the second electrode and the ZnO layer is a transparent outermost layer that is directly adjacent to the Cu—Cd—Ni spinel chromite layer.

In some embodiments, the photodiode has a reactivity (R) of greater than or equal to 15 milliampere per watt (mA/W) when exposed to a stable pulse with a voltage of 1 volt (V) and an ultraviolet (UV) light power of 69 milliwatt (mW).

In some embodiments, the photodiode has a R value of greater than or equal to 20 mA/W when exposed to a stable pulse with a voltage of 1 V and a UV light power of 69 mW.

In some embodiments, the photodiode has a R value of greater than or equal to 25 mA/W when exposed to a stable pulse with a voltage of 1 V and a UV light power of 69 mW.

In some embodiments, the photodiode has a R value of 26.667 mA/W when exposed to a stable pulse with a voltage of 1 V and a UV light power of 69 mW.

In some embodiments, the photodiode has a detectivity of (D) of greater than or equal to 2.0 Jones when exposed to a stable pulse with a voltage of 1 V and a UV light power of 69 mW.

In some embodiments, the photodiode has a D value of greater than or equal to 2.5 Jones when exposed to a stable pulse with a voltage of 1 V and a UV light power of 69 mW.

In some embodiments, the photodiode has a D value of greater than or equal to 2.70 Jones when exposed to a stable pulse with a voltage of 1 V and a UV light power of 69 mW.

In some embodiments, the photodiode has a D value of 2.76 Jones when exposed to a stable pulse with a voltage of 1 V and a UV light power of 69 mW.

In some embodiments, the photodiode has a decay time (t_{decay}) less than or equal to 1.5 second (s) when exposed to a stable pulse with a voltage of 1 V and a UV light power of 69 mW.

In some embodiments, the photodiode has a t_{decay} less than or equal to 1.25 s when exposed to a stable pulse with a voltage of 1 V and a UV light power of 69 mW.

In some embodiments, the photodiode has a t_{decay} less than or equal to 1 s when exposed to a stable pulse with a voltage of 1 V and a UV light power of 69 mW.

In some embodiments, the photodiode has a t_{decay} of 0.95 s when exposed to a stable pulse with a voltage of 1 V and a UV light power of 69 mW.

In some embodiments, the photodiode has a rise time (tᵣᵢₛₑ) of less than or equal to 1.5 s when exposed to a stable pulse with a voltage of 1 V and a UV light power of 69 mW.

In some embodiments, the photodiode has a tᵣᵢₛₑ of less than or equal to 1 s when exposed to a stable pulse with a voltage of 1 V and a UV light power of 69 mW.

In some embodiments, the photodiode has a tᵣᵢₛₑ of less than or equal to 0.75 s when exposed to a stable pulse with a voltage of 1 V and a UV light power of 69 mW.

In some embodiments, wherein the photodiode has a bias in a range from 0.75 to 1.25 V when exposed to a stable pulse with a voltage of 1 V and a UV light power of 69 mW.

In some embodiments, wherein the photodiode has a bias in a range from 0.85 to 1.15 V when exposed to a stable pulse with a voltage of 1 V and a UV light power of 69 mW.

In some embodiments, the photodiode has a bias of 1 V when exposed to a stable pulse with a voltage of 1 V and a UV light power of 69 mW.

In some embodiments, the photodiode has a R value of 26.6 mA/W, a D value of 2.76 Jones, and a t_{decay} of 0.95 s when exposed to a stable pulse with a voltage of 1 V and a UV light power of 69 mW.

The foregoing general description of the illustrative embodiments and the following detailed description thereof are merely exemplary aspects of the teachings of this disclosure, and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 is a schematic diagram of the structure of the photodiode based on the copper-cadmium-nickel chromium oxide (Cu_{0.4}Cd_{0.3}Ni_{0.3}Cr₂O₄) spinel oxide, according to certain embodiments.

FIG. 2 is a graph depicting time-dependent variation of the photocurrent under various ultraviolet (UV) illumination powers at a voltage of 1 volt (V) for photodiode based on the Cu_{0.4}Cd_{0.3}Ni_{0.3}Cr₂O₄ spinel oxide, according to certain embodiments, with an inset showing the 69 mW illumination graph.

FIG. 3 is a graph depicting variation of the photocurrent as a function of time under a UV light power of 69 milliwatt (mW) and a voltage of 1 V for a stable pulse on the Cu_{0.4}Cd_{0.3}Ni_{0.3}Cr₂O₄ spinel oxide, according to certain embodiments.

### DETAILED DESCRIPTION

When describing the present disclosure, the terms used are to be construed in accordance with the following definitions, unless a context dictates otherwise.

Embodiments of the present disclosure will now be described more fully hereinafter with reference to the accompanying drawings wherever applicable, in that some, but not all, embodiments of the disclosure are shown.

In the drawings, like reference numerals designate identical or corresponding parts throughout the several views. Further, as used herein, the words ‘a’, ‘an’ and the like generally carry a meaning of ‘one or more’, unless stated otherwise.

Furthermore, the terms ‘approximately,’ ‘approximate’, ‘about’ and similar terms generally refer to ranges that include the identified value within a margin of 20%, 10%, or preferably 5%, and any values therebetween.

In this disclosure, a numerical value interval (i.e., a numerical value range) is involved, and, if not specifically stated, an optional numerical value distribution is considered continuous within the numerical value interval, and includes two numerical value endpoints (i.e., minimum and maximum values) of the numerical value range, and each numerical value between the two numerical value endpoints.

As used herein, the term ‘electrode’ refers to an electrical conductor used to contact a non-metallic part of a circuit, such as a semiconductor, an electrolyte, a vacuum, or air.

As used herein, the term ‘photodiode’ refers to a semiconductor device that converts light into an electrical current. When photons (light particles) hit the photodiode, they generate electron-hole pairs, creating a current that can be measured. Photodiodes are often used in applications like optical communication, light detection, and imaging systems.

As used herein, the term ‘solar cell’ refers to a device that converts light energy, typically sunlight, into electrical energy through the photovoltaic effect.

As used herein, the term ‘ultraviolet (UV) light’ refers to an electromagnetic radiation with wavelengths between 10 nanometer (nm) and 400 nm, shorter than visible light. It has high energy and can excite electrons in semiconductor materials, making it useful for photodetection and energy conversion applications. In photodiodes, UV light generates electron-hole pairs, contributing to photocurrent and device performance.

As used herein the term ‘sol-gel method’ refers to a chemical process used to produce solid materials from a liquid sol (a colloidal suspension of particles in a solvent). This method involves transitioning from a liquid sol to a solid gel through hydrolysis and polymerization reactions, typically under controlled conditions.

As used herein, the term ‘spinel layer’ refers to a thin layer of a spinel-phase material, which is a type of crystal structure characterized by the general formula AB₂O₄. Where, A and B represent metal ions, and O represents oxygen. Spinel structures are known for their stability and versatility in a range of materials, such as metal oxides.

As used herein, the term ‘decay time (t_{decay})’ refers to the amount of time it takes for a quantity, such as a signal, current, or intensity, to decrease to a certain fraction of its initial value after a disturbance or excitation. In many contexts, decay time is associated with the time it takes for a physical or chemical process to return to equilibrium after being perturbed.

As used herein, the term ‘rise time (tᵣᵢₛₑ)’ refers to the amount of time it takes for a signal or physical quantity to change from a lower value to a higher value, typically from 10% to 90% of its maximum value. It is commonly used to describe how quickly a system or signal responds to an input or stimulus.

As used herein, the term ‘reactivity’ refers to the responsiveness or sensitivity of a photodiode to light or electromagnetic radiation. It describes how effectively a photodiode reacts to the presence of light by generating a measurable electrical current in response to absorbed photons.

As used herein, the term ‘detectivity’ refers to a measure of the sensitivity of a photodiode to weak light signals. It quantifies how effectively the photodiode can detect light in the presence of noise and is typically expressed in terms of the specific detectivity.

A weight percent of a component, unless specifically stated to the contrary, is based on the total weight of the formulation or composition in which the component is included. For example, if a particular element or component in a composition or article is said to have 5 weight percent (wt. %), it is understood that this percentage is in relation to a total compositional percentage of 100%.

The present disclosure is intended to include all hydration states of a given compound or formula, unless otherwise noted or when heating a material.

In addition, the present disclosure is intended to include all isotopes of atoms occurring in the present compounds and complexes. Isotopes include those atoms having the same atomic number but different mass numbers. By way of general example, and without limitation, isotopes of hydrogen include deuterium and tritium, and isotopes of carbon include ¹³C and ¹⁴C. Isotopes of oxygen include ¹⁶O, ¹⁷O, and ¹⁸O. Isotopes of naturally occurring nickel ²⁸Ni include ⁵⁸Ni, ⁶⁰Ni, ⁶¹Ni, ⁶²Ni, and ⁶⁴Ni. Isotopically-labeled compounds of the disclosure may generally be prepared by conventional techniques known to those skilled in the art or by processes analogous to those described herein, using an appropriate isotopically-labeled reagent in place of the non-labeled reagent otherwise employed.

Aspects of this disclosure are directed to a method of developing a photodiode, and more particularly, a photodiode including copper-cadmium-nickel chromium (Cu—Cd—Ni) spinel chromite, synthesized using the sol-gel method. The photodiode demonstrated desirable reactivity and detectivity under ultraviolet (UV) light. These findings suggest that this material can enhance the efficiency of UV photodetectors for a wide range of applications.

A photodiode including (Cu_{0.4}Cd_{0.3}Ni_{0.3}Cr₂O₄) spinel oxide is described. Spinel oxides having AB₂O₄(A═Mn, Cu, Cd, Co, Zn, Fe, Ni; B═Cr, Ni, Mn, Mo, Co) formula have normal, inverse, or complex structures determined by cation occupation of octahedral (Oh) or tetrahedral (Td) sites. This mixed-metal spinel structure allows for the stability of the lattice through a balanced distribution of ions, with each metal ion occupying a site that suits its size, charge, and coordination preference.

The photodiode includes a first electrode having an indium gallium (InGa) layer, a second electrode having a zinc oxide (ZnO) layer, and a Cu—Cd—Ni spinel chromite layer including the Cu_{0.4}Cd_{0.3}Ni_{0.3}Cr₂O₄ oxide. The Cu—Cd—Ni spinel chromite layer is present in a layer between the first electrode and the second electrode where the ZnO layer is a transparent outermost layer that is directly adjacent to the Cu—Cd—Ni spinel chromite layer. This arrangement allows the spinel chromite layer to effectively absorb light and generate photocurrents. The transparent ZnO layer provides efficient light transmission and protection to the spinel chromite layer, thereby improving the performance of the device. Additionally, the interface between the spinel chromite and electrodes helps facilitate charge transport, reducing energy losses and increasing overall efficiency.

In some embodiments, the photodiode has a reactivity (R) of greater than or equal to 10 milliampere per watt (mA/W), preferably 15 mA/W, preferably greater than or equal to 16 mA/W, preferably greater than or equal to 17 mA/W, preferably greater than or equal to 18 mA/W, preferably greater than or equal to 19 mA/W, greater than or equal to 20 mA/W, preferably greater than or equal to 21 mA/W, preferably greater than or equal to 22 mA/W, preferably greater than or equal to 23 mA/W, preferably greater than or equal to 24 mA/W, and preferably greater than or equal to 25 mA/W, when exposed to a stable pulse with a voltage of 1 volt (V) and a UV light power of 69 milliwatt (mW).

In some embodiments, the photodiode has a R of greater than or equal to 25 mA/W, preferably greater than or equal to 25.1 mA/W, preferably greater than or equal to 25.2 mA/W, preferably greater than or equal to 25.3 mA/W, preferably greater than or equal to 25.4 mA/W, preferably greater than or equal to 25.5 mA/W, preferably greater than or equal to 25.6 mA/W, preferably greater than or equal to 25.7 mA/W, preferably greater than or equal to 25.8 mA/W, preferably greater than or equal to 25.9 mA/W, preferably greater than or equal to 26 mA/W, preferably greater than or equal to 26.1 mA/W, preferably greater than or equal to 26.2 mA/W, preferably greater than or equal to 26.3 mA/W, preferably greater than or equal to 26.4 mA/W, preferably greater than or equal to 26.5 mA/W, preferably greater than or equal to 26.6 mA/W, preferably greater than or equal to 26.7 mA/W, preferably greater than or equal to 26.8 mA/W, and preferably greater than or equal to 26.9 mA/W when exposed to a stable pulse with a voltage of 1 V and a UV light power of 69 mW. In a preferred embodiment, the photodiode has a R of 26.667 mA/W when exposed to a stable pulse with a voltage of 1 V and a UV light power of 69 mW.

In some embodiments, the photodiode has a detectivity of (D) of greater than or equal to 1.0 Jones, preferably greater than or equal to 2.0 Jones, preferably greater than or equal to 2.1 Jones, preferably greater than or equal to 2.2 Jones, preferably greater than or equal to 2.3 Jones, preferably greater than or equal to 2.4 Jones, greater than or equal to 2.5 Jones, preferably greater than or equal to 2.6 Jones, preferably greater than or equal to 2.7 Jones, and preferably greater than or equal to 2.8 Jones when exposed to a stable pulse with a voltage of 1 V and a UV light power of 69 mW.

In some embodiments, the photodiode has a D of greater than or equal to 2.7 Jones, preferably greater than or equal to 2.71 Jones, preferably greater than or equal to 2.72 Jones, preferably greater than or equal to 2.73 Jones, preferably greater than or equal to 2.74 Jones, preferably greater than or equal to 2.75 Jones, preferably greater than or equal to 2.76 Jones, when exposed to a stable pulse with a voltage of 1 V and a UV light power of 69 mW. In a preferred embodiment, the photodiode has a D of 2.76 Jones when exposed to a stable pulse with a voltage of 1 V and a UV light power of 69 mW.

In some embodiments, the photodiode has a t_{decay} less than or equal to 2.5 second (s), preferably 1.5 s, preferably less than or equal to 1.4 s, preferably less than or equal to 1.3 s, preferably less than or equal to 1.2 s, preferably less than or equal to 1.1 s, preferably less than or equal to 1.0 s, preferably less than or equal to 0.95 s when exposed to a stable pulse with a voltage of 1 V and a UV light power of 69 mW. In a preferred embodiment, the photodiode has a t_{decay} value of 0.95 s when exposed to a stable pulse with a voltage of 1 V and a UV light power of 69 mW.

In some embodiments, the photodiode has a tᵣᵢₛₑ value of less than or equal to 2.5 s, preferably 1.5 s, preferably less than or equal to 1.4 s, preferably less than or equal to 1.3 s, preferably less than or equal to 1.2 s, preferably less than or equal to 1.1 s, less than or equal to 1 s, preferably less than or equal to 0.9 s, preferably less than or equal to 0.8 s, and preferably less than or equal to 0.75 s when exposed to a stable pulse with a voltage of 1 V and a UV light power of 69 mW. In a preferred embodiment, the photodiode has a tᵣᵢₛₑ value of 0.73 s.

In some embodiments, the photodiode has a bias in a range from 0.25-1.75 V, preferably 0.75-1.25 V, preferably 0.76-1.24 V, preferably 0.78-1.22 V, preferably 0.80-1.20 V, preferably 0.82-1.18 V, preferably 0.84-1.16 V, preferably 0.86-1.14 V, preferably 0.88-1.12 V, preferably 0.90-1.10 V, preferably 0.92-1.08 V, preferably 0.94-1.06 V, preferably 0.96-1.04 V, and preferably 0.98-1.02 V. In a preferred embodiment, the photodiode has a bias of 1 V when exposed to a stable pulse with a voltage of 1 V and a UV light power of 69 mW.

In a preferred embodiment, the photodiode has a R value of 26.6 mA/W, a D value of 2.76 Jones, and a t_{decay} of 0.95 s when exposed to a stable pulse with a voltage of 1 V and a UV light power of 69 mW.

### EXAMPLES

The following examples demonstrate a photodiode based on copper-cadmium-nickel chromium spinel oxide (Cu_{0.4}Cd_{0.3}Ni_{0.3}Cr₂O₄). The examples are provided solely for illustration and are not to be construed as limitations of the present disclosure, as many variations thereof are possible without departing from the spirit and scope of the present disclosure.

### Example 1: Production of Photodiodes

According to the present disclosure, the procedure began with the preparation of a glass substrate, which served as the photodiode's substrate. The indium gallium (InGa) electrode was deposited as a gel on the glass substrate using a spin-coating process. The InGa electrode generates and collects photo-induced charges. The spinel substance, which had previously been prepared as a powder, was then dissolved in nitric acid (HNO₃) and the resulting solution was then spin-coated onto the InGa layer, providing a uniform spinel deposit on the substrate. This step achieved uniform distribution of the active components in the photodiode. After the spinel was deposited, the copper/zinc (Cu/Zn) electrode was applied to finalize the junction structure.

Further exposing to ultraviolet (UV) light, the Cu/Zn electrode, combined with the InGa electrode generated the electric field required for the creation and collection of charge carriers.

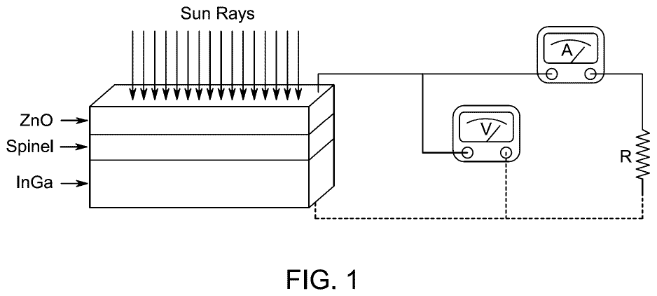

Further, to activate the photodiode, a voltage was applied across the two electrodes, and the current generated was measured. This measurement examines the photodiode's performance, specifically its response to incident photons and its ability to convert light energy into an electrical signal. FIG. 1 is a schematic diagram of the structure of the photodiode based on the copper-cadmium-nickel chromium oxide (Cu_{0.4}Cd_{0.3}Ni_{0.3}Cr₂O₄) spinel oxide.

### Example 2: Current-Time (I-t) Characteristics of Photodiode-Based Cu—Cd—Ni Spinel Chromite

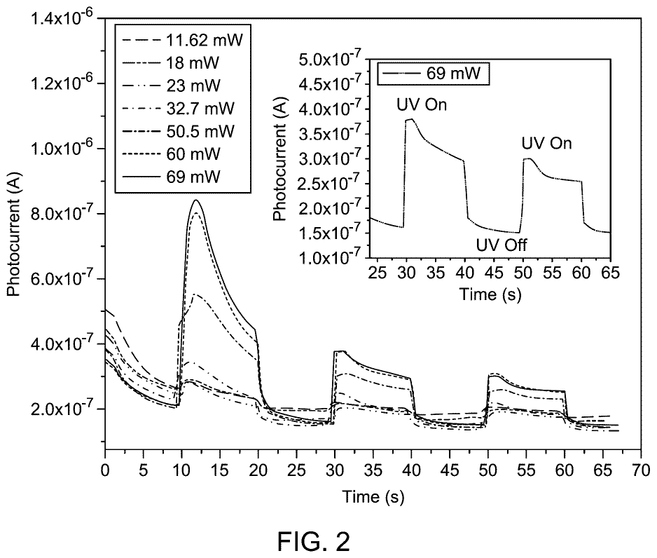

The photocurrent variations as a function of time for photodiodes-based spinel oxide, for different incident light power P, are shown in FIG. 2, When the 375 nanometer (nm) laser is switched on and off, each UV photodetector exhibits reversible switching between low and high photoconductive states. An immediate rise in photocurrent to saturation occurs upon UV illumination, followed by an abrupt decrease in photo response when the UV illumination is turned off. This observation suggests that UV light excites electrons confined in defect levels towards the conduction band, enhancing the photo response of the device. Moreover, a rise in light power (P) was observed followed by an increase in the photocurrent variations, indicating an increase in the photo response of the device.

### Example 3: Performance Parameters of Photodiode Based on Cu—Cd—Ni Spinel Chromite

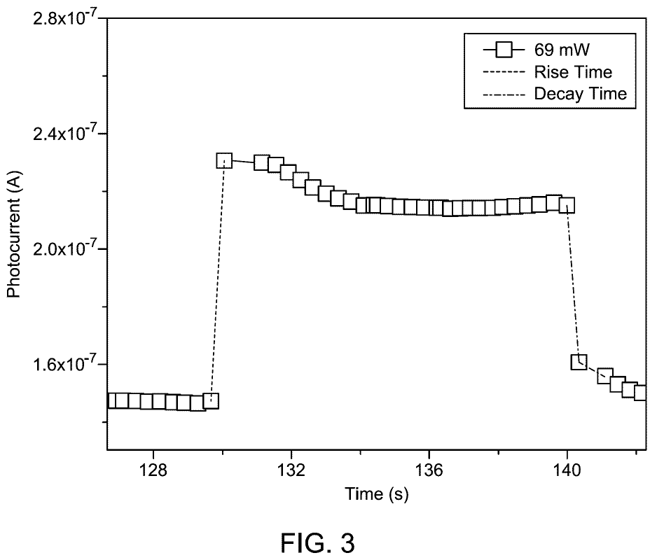

FIG. 3 depicts the variation of photocurrent as a function of time for a stable pulse with a voltage of 1 V and a UV light power of 69 milliwatt (mW). Measuring response time was useful for assessing photodetector performance, as it showed the detector's reactivity and accuracy to incident light. The rise time, also known as tᵣᵢₛₑ, referred to the time required for the photodiode's current to reach 90 percent (%) of its maximum value after being exposed to light. A shorter rise time suggested that the photodiode responded quickly to changes in incident light levels. The decay time (t_{decay}) represented the time required for the photodiode's photocurrent to diminish by 10% from its peak value once the light source was removed. A shorter decay time reflected how swiftly the photodiode could restore or revert to its initial condition after light exposure. In Table 1, the performances of UV photodetectors based on Cu—Cd—Ni spinel ferrite with the results obtained from various photodetectors designed for photodetection applications were compared. The tᵣᵢₛₑ and t_{decay} values obtained in the present study for the photodiode based on Cu_{0.4}Cd_{0.3}Ni_{0.3}Cr₂O₄ spinel were lower than those reported in previous research. Results, however, exceeded those of photodiodes generated using ferrites such as zinc ferrite (ZnFe₂O₄) and iron doped bismuth ferrite (Fe-doped BiFeO₃).

TABLE 1
Comparison of the performance of UV photodetector based on Cu—Cd—Ni
spinel chromite with those obtained in other studies.

| | | | | Reactivity | D × 10¹⁰ | |
|---|---|---|---|---|---|---|
| Sample | Bias (V) | tᵣᵢₛₑ (s) | t_{decay} (s) | (mA/W) | (Jones) | Ref. |
| CNT-impregnated | 2 | 16 | 41 | 2.1 × 10 | — | [1] |
| ZnO nanourchins | | | | | | |
| ZnO:Ni (3%) | 5 | 13 | 8 | 5.43 | 0.0662 | [2] |
| ZnO:Ni (7%) | | 0.5 | 2 | 7.52 | 0.0792 | |
| ZnO/Si:GaN | 0.5 | 29 | 141 | 960 | 0.487 | [3] |
| Mn doped ZnO | 1 | 16.2 | 59.5 | 25.58 | 1.57 | [4] |
| BiFe_{0.95}Zr_{0.05}O₃ | | 0.192 | 0.186 | 18 | 8.72 | [5] |
| ZnFe₂O₄ thin film | 0 | 0.1 | — | 4.8 | 29.8 | [6] |
| Cu_{0.4}Cd0.3Ni_{0.3}Cr₂O₄ | 1 | 0.73 | 0.95 | 26.667 | 2.76 | Present |
| | | | | | | work |

[1] Safa., S., Enhanced UV-detection properties of carbon nanotube impregnated ZnO nanourchins, Optik - International Journal for Light and Electron Optics, Volume 126, Issue 19, 2015, pages 2194-2198.
[2] Abbasi, F. et al.,, Performance improvement of UV photodetectors using Cd-doped ZnO nanostructures, J Mater Sci: Mater Electron, 32, 19614-19625, 2021.
[3] Anitha, R., et al., Large area ultraviolet photodetector on surface modified Si:GaN layers, Applied Surface Science, Volume 435, 2018, pages 1057-1064.
[4] Sugumar, R., et al., Influence of substrate heating and annealing on the properties and photoresponse of manganese doped zinc oxide thin films, Superlattices and Microstructures, Volume 110, 2017, pages 57-67.
[5] Kathirvel, A., et al., Enhanced responsivity of Zr-doped BiFeO3 based self-powered UV-visible heterojunction photodetector fabricated via spray pyrolysis technique, Applied Surface Science, Volume 618, 2023, 156640.
[6] Tran, M. et al., Facile fabrication of low-defect spinel zinc ferrite oxide thin film for high-performance ultraviolet photodetector, Journal of Alloys and Compounds, Volume 970, 2024, 172422, each incorporated herein by reference in their entirety.

[1] Safa., S., Enhanced UV-detection properties of carbon nanotube impregnated ZnO nanourchins, Optik—International Journal for Light and Electron Optics, Volume 126, Issue 19, 2015, pages 2194-2198.
[2] Abbasi, F. et al., Performance improvement of UV photodetectors using Cd-doped ZnO nanostructures, J Mater Sci: Mater Electron, 32, 19614-19625, 2021.
[3] Anitha, R., et al., Large area ultraviolet photodetector on surface modified Si:GaN layers, Applied Surface Science, Volume 435, 2018, pages 1057-1064.
[4] Sugumar, R., et al., Influence of substrate heating and annealing on the properties and photoresponse of manganese doped zinc oxide thin films, Superlattices and Microstructures, Volume 110, 2017, pages 57-67.
[5] Kathirvel, A., et al., Enhanced responsivity of Zr-doped BiFeO₃ based self-powered UV-visible heterojunction photodetector fabricated via spray pyrolysis technique, Applied Surface Science, Volume 618, 2023, 156640.
[6] Tran, M. et al., Facile fabrication of low-defect spinel zinc ferrite oxide thin film for high-performance ultraviolet photodetector, Journal of Alloys and Compounds, Volume 970, 2024, 172422, each incorporated herein by reference in their entirety.

To conclude, the quicker rise time found for the photodiode based on Cu—Cd—Ni spinel chromite indicated that it could rapidly convert incoming light into an electrical signal. Additionally, the faster fall time lead to a swift response to changes in illumination, facilitating precise signal processing and enabling rapid transitions between light states. The data presented in this table clearly demonstrated that the performances of the current material, particularly its detectivity (D), were similar to those seen in other oxide materials. The findings underscored the useful nature of the manufactured UV photodetector and its promise for a range of ultraviolet light detection applications.

Numerous modifications and variations of the present disclosure are possible in light of the above teachings. It is therefore to be understood that within the scope of the appended claims, the disclosure may be practiced otherwise than as specifically described herein.

1. A photodiode, comprising:
a first electrode having an indium gallium (InGa) layer;
a second electrode having a zinc oxide (ZnO) layer; and
a copper-cadmium-nickel (Cu—Cd—Ni) spinel chromite layer comprising copper-cadmium-nickel chromium (Cu_{0.4}Cd_{0.3}Ni_{0.3}Cr₂O₄) oxide,
wherein the Cu—Cd—Ni spinel chromite layer is present in a layer between the first electrode and the second electrode,
wherein the ZnO layer is a transparent outermost layer that is directly adjacent to the Cu—Cd—Ni spinel chromite layer.

2. The photodiode of claim 1, wherein the photodiode has a reactivity (R) of greater than or equal to 15 milliampere per watt (mA/W) when exposed to a stable pulse with a voltage of 1 volt (V) and ultraviolet (UV) light power of 69 milliwatt (mW).

3. The photodiode of claim 2, wherein the photodiode has a R of greater than or equal to 20 mA/W when exposed to a stable pulse with a voltage of 1 V and a UV light power of 69 mW.

4. The photodiode of claim 3, wherein the photodiode has a R of greater than or equal to 25 mA/W when exposed to a stable pulse with a voltage of 1 V and a UV light power of 69 mW.

5. The photodiode of claim 4, wherein the photodiode has a R of 26.667 mA/W when exposed to a stable pulse with a voltage of 1 V and a UV light power of 69 mW.

6. The photodiode of claim 1, wherein the photodiode has a detectivity of (D) of greater than or equal to 2.0 Jones when exposed to a stable pulse with a voltage of 1 V and a UV light power of 69 mW.

7. The photodiode of claim 6, wherein the photodiode has a D of greater than or equal to 2.5 Jones when exposed to a stable pulse with a voltage of 1 V and a UV light power of 69 mW.

8. The photodiode of claim 7, wherein the photodiode has a D of greater than or equal to 2.70 Jones when exposed to a stable pulse with a voltage of 1 V and a UV light power of 69 mW.

9. The photodiode of claim 8, wherein the photodiode has a D of 2.76 Jones when exposed to a stable pulse with a voltage of 1 V and a UV light power of 69 mW.

10. The photodiode of claim 1, wherein the photodiode has a decay time (t_{decay}) less than or equal to 1.5 second (s) when exposed to a stable pulse with a voltage of 1 V and a UV light power of 69 mW.

11. The photodiode of claim 10, wherein the photodiode has a t_{decay} less than or equal to 1.25 s when exposed to a stable pulse with a voltage of 1 V and a UV light power of 69 mW.

12. The photodiode of claim 11, wherein the photodiode has a t_{decay} less than or equal to 1 s when exposed to a stable pulse with a voltage of 1 V and a UV light power of 69 mW.

13. The photodiode of claim 12, wherein the photodiode has a t_{decay} of 0.95 s when exposed to a stable pulse with a voltage of 1 V and a UV light power of 69 mW.

14. The photodiode of claim 1, wherein the photodiode has a rise time (tᵣᵢₛₑ) of less than or equal to 1.5 s when exposed to a stable pulse with a voltage of 1 V and a UV light power of 69 mW.

15. The photodiode of claim 14, wherein the photodiode has a tᵣᵢₛₑ of less than or equal to 1 s when exposed to a stable pulse with a voltage of 1 V and a UV light power of 69 mW.

16. The photodiode of claim 15, wherein the photodiode has a tᵣᵢₛₑ of less than or equal to 0.75 s when exposed to a stable pulse with a voltage of 1 V and a UV light power of 69 mW.

17. The photodiode of claim 1, wherein the photodiode has a bias in a range from 0.75 to 1.25 V when exposed to a stable pulse with a voltage of 1 V and a UV light power of 69 mW.

18. The photodiode of claim 17, wherein the photodiode has a bias in a range from 0.85 to 1.15 V when exposed to a stable pulse with a voltage of 1 V and a UV light power of 69 mW.

19. The photodiode of claim 18, wherein the photodiode has a bias of 1 V when exposed to a stable pulse with a voltage of 1 V and a UV light power of 69 mW.

20. The photodiode of claim 1, wherein the photodiode has a R value of 26.6 mA/W, a D value of 2.76 Jones, and a t_{decay} of 0.95 s when exposed to a stable pulse with a voltage of 1 V and a UV light power of 69 mW.
